(19) United States
(12) Patent Application Publication
(10) Pub. No.: US 2026/0128069 A1
(43) Pub. Date: May 7, 2026

(54) MEMORY DEVICE AND OPERATION METHOD THEREOF

(71) Applicant: Winbond Electronics Corp., Taichung City (TW)

(72) Inventors: Johnny Chan, Fremont, CA (US); Chi-Shun Lin, Fremont, CA (US)

(73) Assignee: Winbond Electronics Corp., Taichung City (TW)

(21) Appl. No.: 18/935,627

(22) Filed: Nov. 3, 2024

(51) Int. Cl. G11C 7/22; G11C 7/10

(52) U.S. Cl. CPC G11C 7/222; G11C 7/1084; G11C 7/1096

(57) ABSTRACT

A memory device and an operation method thereof are provided. The operation method includes the following steps: receiving a writer mode command to operate the memory device to perform a data write operation by a system control logic; during a data write period of the data write operation, receiving and writing a plurality of word data into a memory buffer by the system control logic, and performing a data program operation by the memory buffer; and during a data program period of the data program operation, programming the plurality of word data into the memory cell by the memory buffer, wherein the data program period is partial overlapped with the data write period.

### BACKGROUND

### Technical Field

The disclosure relates a memory device, particularly, the disclosure relates to a memory device executes system code programming and an operation thereof.

### Description of Related Art

In general, when the traditional memory device executes system code programming, the traditional memory device has to completely write the system code into the memory buffer firstly, and then program the system code into the memory cells according to the system code which is completely written into the memory buffer. Namely, the writing of the system code into the memory buffer ends before the beginning of programing the system code into the memory cells. That is to say, the traditional memory device needs to wait for the writing of the system code into the memory buffer to be completed before programming the system code into the memory cells. Therefore, reducing the required time to execute system code programming (hereinafter referred to as “required programming time”) is limited. In particular, if the system code is longer, the required programming time is also longer, and the required size of the memory buffer is also larger, which is harmful to operational efficiency and miniaturization.

### SUMMARY

The disclosure provides a memory device and an operation method of the memory device to solve the above-mentioned problem.

The operation method of the memory device of the disclosure includes the following steps: receiving a writer mode command to operate the memory device to perform a data write operation by a system control logic; during a data write period of the data write operation, receiving and writing a plurality of word data into a memory buffer by the system control logic, and performing a data program operation by the memory buffer; and during a data program period of the data program operation, programming the plurality of word data into the memory cell by the memory buffer, wherein the data program period is partial overlapped with the data write period.

The memory device includes a memory cell, a memory buffer and a system control logic. The memory buffer is coupled to the memory cell. The system control logic is coupled to the memory buffer. The system control logic is configured to receive a writer mode command to operate the memory device to perform a data write operation. During a data write period of the data write operation, the system control logic receives and writes a plurality of word data into the memory buffer, and the memory buffer performs a data program operation. During a data program period of the data program operation, the memory buffer programs the plurality of word data into the memory cell, and the data program period is partial overlapped with the data write period.

Based on the above, according to the memory device and the operation method thereof of the disclosure, the memory device can effectively reduce the time for system code programming, and also be conducive to miniaturization.

### BRIEF DESCRIPTION OF THE DRAWINGS

FIG. 1 is a schematic diagram of a memory device according to an embodiment of the disclosure.

FIG. 2 is a flow chart of an operation method of a memory device according to an embodiment of the disclosure.

FIG. 3 is a schematic diagram of a memory device according to another embodiment of the disclosure.

FIG. 4 is a schematic diagram of related signals according to the embodiment of FIG. 3 of the disclosure.

FIG. 5 is a schematic diagram of a plurality of flip-flops according to another embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

The term “coupled” used throughout the whole specification of the present application (including the appended claims) may refer to any direct or indirect connection means. For example, if the text describes that a first device is coupled to a second device, it should be interpreted that the first device may be directly connected to the second device, or the first device may be indirectly connected through other devices or certain connection means to be connected to the second device.

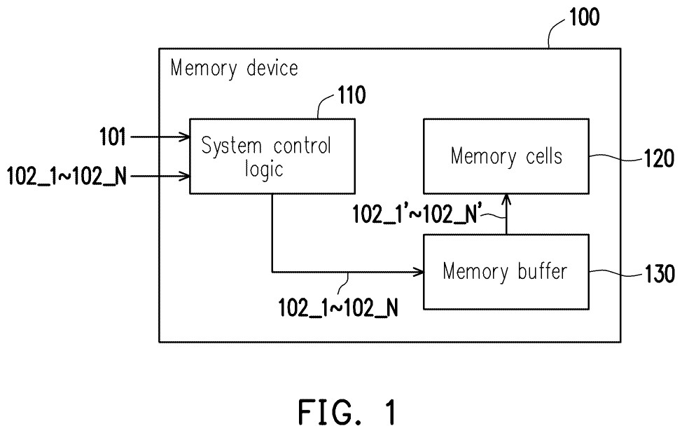

FIG. 1 is a schematic diagram of a memory device according to an embodiment of the disclosure. Referring to FIG. 1, the memory device 100 include a system control logic 110, a plurality of memory cells 120 and a memory buffer 130. The system control logic 110 is coupled to the memory cells 120, and the memory cells 120 are further coupled to the memory buffer 130. In the embodiment of the disclosure, the memory device 100 may be a NOR flash memory, but the disclosure is also not limited thereto. The system control logic 110 may receive a writer mode command 101 and a plurality of word data 102_1 to 102_N, where N is a positive integer. In the embodiment of the disclosure, in response to receiving the writer mode command 101, the memory device 100 performs a data write operation to write the plurality of word data 102_1 to 102_N into memory buffer 130, and during the period when the data write operation for writing the plurality of word data 102_1 to 102_N into the memory buffer 130 is performing, the memory device 100 also performs a data program operation to program the plurality of buffered word data 102_1′ to 102_N′ from the memory buffer 130 into the selected memory cells 120. Accordingly, the present disclosure can reduce the time for data programming, and reduce the required size of the memory buffer. In addition, each word data of the disclosure may include a plurality of data bytes, such as 16 bytes.

In the embodiment of the disclosure, the system control logic 110 is, for example, a central processing unit (CPU), or other programmable general-purpose or special-purpose microprocessor, digital signal processor (DSP), programmable controller, application specific integrated circuits (ASIC), programmable logic device (PLD) or other similar devices or a combination of these devices.

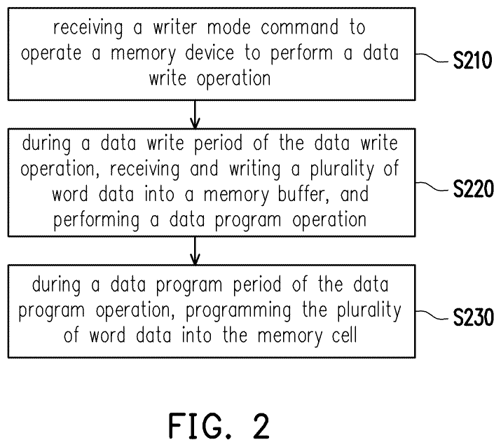

FIG. 2 is a flow chart of an operation method of a memory device according to an embodiment of the disclosure. Referring to FIG. 1 and FIG. 2, the memory device 100 may perform the following steps S210 to S230. In step S210, the system control logic 110 may receive a writer mode command to operate the memory device 100 to perform the data write operation. In step S220, during a data write period of the data write operation, the system control logic 110 may receive and write the plurality of word data 102_1 to 102_N into the memory buffer 130, and provide the buffered word data 102_1′ to 102_N′ from the memory buffer 130 to the selected memory cells 120 to perform the data program operation. In the embodiment of the disclosure, the plurality of word data may include a system code, and the system code is a boot-up code, but the disclosure is not limited thereto. Moreover, the system control logic 110 may receive the plurality of word data 102_1 to 102_N through a serial peripheral interface (SPI) or a quick path interconnect interface (QPI), but the disclosure is also not limited thereto.

In step S230, during a data program period of the data program operation, the memory device 100 may program the plurality of buffered word data 102_1′ to 102_N′ from the memory buffer 130 into the selected memory cells 120. In the embodiment of the disclosure, the data program period may be partial overlapped with the data write period. Specifically, the memory device 100 may start the data write operation and the data program operation sequentially, and then end the data write operation and the data program operation sequentially, so as to reduce the time for data programming. Specifically, the plurality of buffered word data 102_1′ to 102_N′ may include N word data. Firstly, the system control logic 110 may receive and write a first word data of the N word data into the memory buffer 130. Then, while the system control logic 110 receives and writes a second word data of the N word data into the memory buffer 130 in a current word cycle, the first word data has been stored in the memory buffer 130, and the memory buffer 130 may also program the first word data which received from a previous word cycle into the selected memory cells 120. The system control logic 110 writing the last data word into the memory buffer 130 happens after a write command completes with a short program time. Moreover, the word length of the word data is associated with the error correction code (ECC) word length. By analogy, when the system control logic 110 finishes receiving and writing an N-th word data of the N word data into the memory buffer 130, the memory buffer 130 may start to program the (N-1)-th word data into the memory cell 120. That is, after the data write operation is completed, the memory buffer 130 only need program the N-th word data into the selected memory cells 120 during an additional period of one minimum write pulse width (tWP). Therefore, the data program period may be partial overlapped with the data write period in response to receiving the writer mode command, so as to reduce the time for system code programming, and reduce the required size of the memory buffer.

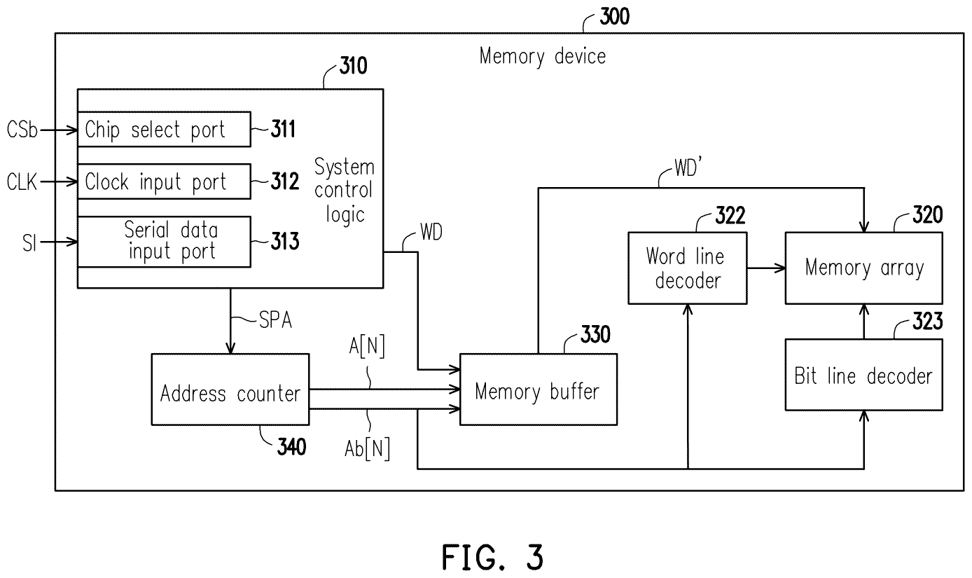

FIG. 3 is a schematic diagram of a memory device according to another embodiment of the disclosure. Referring to FIG. 3, the memory device 300 includes a system control logic 310, a memory array 320, a word line decoder 322 and a bit line decoder 323, a memory buffer 330 and an address counter 340. The system control logic 310 is coupled to the memory buffer 330 and the address counter 340. The memory buffer 330 is further coupled to the memory array 320. The address counter 340 is further coupled to the memory buffer 330, the word line decoder 322 and the bit line decoder 323. In the embodiment of the disclosure, the memory array 320 may include the memory cells 120 as shown in FIG. 1.

In the embodiment of the disclosure, the system control logic 310 may receive a chip select signal CSb by a chip select port 311, receive a clock signal CLK by a clock input port 312, and receive a serial data signal SI by a serial data input port 313. The serial data signal SI may include a writer mode command WMC, a starting programming address SPA and a plurality of word data WD. In response to the writer mode command, the system control logic 310 may provide the starting programming address SPA to the address counter 340, so that the address counter 340 may generate a write word address A[N] to the memory buffer 330 via a write word address line 304, and generate a program word address Ab[N] to the memory buffer 330, the word line decoder 322 and the bit line decoder 323 via a program word address line 305. During a data write period PW, the memory device 300 may sequentially write the plurality of word data WD into the memory buffer 330 according to the write word address A[N], such that the memory buffer 330 stores a plurality of buffered word data WD′. During a data program period PP, the memory device 300 may sequentially program the plurality of word data WD′ into the memory cell of the memory array 320 from the memory buffer 330 according to the program word address. The plurality of word data WD′ is the plurality of word data WD stored into the memory buffer 330. The address counter 340 may provide the program word address to the word line decoder 322 and the bit line decoder 323 of the memory cell 320, so that the memory buffer 330 may program the plurality of word data WD′ into the memory cell of the memory array 320.

In the embodiment of the disclosure, the memory buffer 330 may further include two word buffer for alternately writing data and programming data. Specifically, the memory buffer 330 may further include a first word buffer and a second word buffer. The address counter may generate a write control command and a program control command to the memory buffer 330, so as to assign one of the first word buffer and the second word buffer of the memory buffer 330 for performing the data write operation according to the write control command, and assign another one of the first word buffer and the second word buffer of the memory buffer 330 for performing the data program operation according to the program control command. In other words, the memory buffer 330 just use two word buffer to perform the data write operation and the data program operation, instead of using a larger buffer space to store all of the plurality of word data WD. Thus, the memory device 300 may effectively save the use of memory space of the memory buffer 330 in the data write operation and the data program operation.

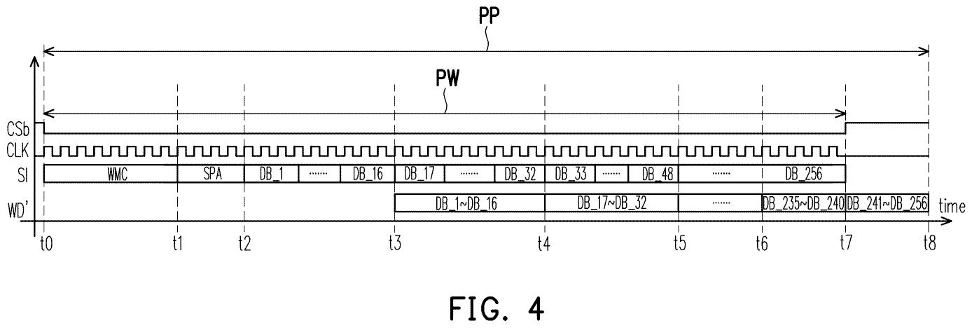

FIG. 4 is a schematic diagram of related signals according to the embodiment of FIG. 3 of the disclosure. Referring to FIG. 3 and FIG. 4, taking the 256-bytes system code (i.e. (data byte DB_1 to DB_256)) as an example of the word data WD and word data WD′, and the 256-bytes system code may be the boot-up code. The system control logic 310 may receive the chip select signal CSb, the clock signal CLK and the serial data signal SI′. During the period of time t0 to time t7 the chip select signal CSb is changed from a first voltage level to a second voltage level. The first voltage level may be a high voltage level, and the second voltage level may be a low voltage level. At time t0, when the voltage level of the chip select signal CSb is changed from the first voltage level to the second voltage level, the system control logic 310 starts to receive the writer mode command WMC according to the chip select signal CSb. During the period from time t0 to time t1, the system control logic 310 receive the writer mode command WMC, and the system control logic 310 may be trigged to perform the data write operation according to the writer mode command WMC. During the period from time t1 to time t2, the system control logic 310 may receive the starting programming address SPA according to the chip select signal CSb, and the starting programming address SPA may be a 24-bytes data, but the disclosure is also not limited thereto.

During the data write period from time t2 to time 7, the memory device 300 perform the data write operation, and the address counter 340 may provide the write word address to the memory buffer 330. During the data program period from time t3 to time t8, the address counter 340 may provide the program word address to the memory buffer 330, the word line decoder 322 and the bit line decoder 323 according to the starting programming address SPA. The memory buffer 320 programs the plurality of word data into the memory cell of the memory array 320 according to the starting programming address SPA. During the period from time t3 to time t4, the system control logic 310 may write the first word data (data bytes DB_1 to DB_16 (i.e. the word data WD)) into the first word buffer of the memory buffer 330 according to the write control command and the write word address.

During the period from time t4 to time t5, the system control logic 310 may write the second word data (data bytes DB_17 to DB_32 (i.e. the word data WD)) into the second word buffer of the memory buffer 330 according to the write control command and the write word address, and the memory device 300 may program the first word data (data bytes DB_1 to DB_16 (i.e. the word data WD′)) into the memory cell of the memory array 320 from the first word buffer of the memory buffer 330 according to the program control command and the program word address. In the embodiment of the disclosure, there is a data write clock latency 403 between the start time t3 of the write data period 401 and the start time t4 of the data program period 402, the data write clock latency may be related to an error correction code (ECC) word length (i.e. 16-bytes). As shown in FIG. 4, the data program period 402 is partial overlapped with the data write period 401. More specifically, when the plurality of word data is read out from the memory cell of the memory array 320, the system control logic 310 may further execute an error correcting code (ECC) operation, so as to self-correct the error data. That is, the memory device 300 must wait for the plurality of word data of the ECC operation to be completed before read out from the memory cell of the memory array 320.

And so on, at time t7, the voltage level of the chip select signal CSb is changed from the second voltage level to the first voltage level, and the system control logic 310 finishes to receive and write the final word data (data bytes DB_241 to DB_260 (i.e. the word data WD)) into the second word buffer of the memory buffer 330. During the period from time t7 to time t8, the memory device 300 may program the final word data (data bytes DB_241 to DB_256 (i.e. the word data WD′)) into the memory cell 321 from the second word buffer of the memory buffer 330 according to the program control command and the program word address. At time t8, when the system control logic 310 finishes receiving and writing the final word data into the memory buffer 330, the memory buffer 330 starts to program the final word data into the memory cell 320. That is, after the data write operation is completed, the memory device 300 continues to perform the data program operation, and the memory buffer 130 only need program the N-th word data into the memory cell 120 during an additional period 404 of one minimum write pulse width (tWP). Therefore, due to the memory device 100 may synchronously perform the data write operation and the data program operation on a part of word data of the system code, so as to reduce the time for system code programming.

In addition, the memory device 300 may perform a normal program operation by using a first program bias voltage, and the memory device 300 may perform the data program operation by using a second program bias voltage, wherein the first program bias voltage is different from the second program bias voltage. In one embodiment of the disclosure, the second program bias voltage is higher than the first program bias voltage. In other word, the memory device 300 may use the optimized program bias voltage for pre-cycling operation to also reduce the time for system code programming.

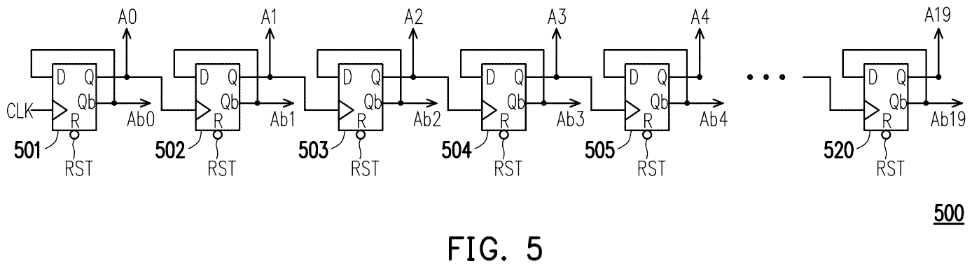

FIG. 5 is a schematic diagram of a plurality of flip-flops according to another embodiment of the disclosure. Referring to FIG. 5, the address counter of the disclosure may be implemented as an address counter 500 of FIG. 5, and include a plurality of flip-flops 501 to 520. In the embodiment of the disclosure, the address counter 500 may be an 8 Mb (megabytes) SPI NOR writer mode address counter, but the disclosure is also not limited thereto. In the embodiment of the disclosure, each one of the flip-flops 501 to 520 may include a data input terminal (D), a data output terminal (Q), an inverse data output terminal (Qb), a clock input terminal, and a reset terminal (R). The clock input terminal of the each one of the flip-flops 501 to 520 may receive a clock signal CLK. The reset terminal (R) of the each one of the flip-flops 501 to 520 may receive the reset signal RST. The data input terminal (D) of the each one of the flip-flops 501 to 520 may receive an output from the inverse data output terminal (Qb).

The data output terminals (Q) of the flip-flops 501 to 520 may output counter signals A0 to A19 to compose an 8 Mb counter information, and the inverse data output terminal (Qb) of the flip-flops 501 to 520 may output inverse counter signals Ab0 to Ab19. The address counter 500 may generate the above the write word address and the program word address according to the counter signals A0 to A19. In the embodiment of the disclosure, the data output terminal (Q) and the inverse data output terminal (Qb) of the flip-flop 505 may be configured as the write control command and the program control command.

Specifically, referring to FIG. 3 to FIG. 5, due to one word data is the 16-bytes data, when the counter signal A4 and the inverse counter signal Ab4 of the flip-flop 505 are transformed respectively, it means that the address counter 500 has counted 16-bytes.

For example, in a first word cycle (count 16-bytes), the counter signal A4 may correspond to bit number “0” and the inverse counter signal Ab4 may correspond to bit number “1”. Thus, the memory buffer 330 may perform the data write operation by using the first word buffer, and perform the data program operation by using the second word buffer. In a second word cycle (count next 16-bytes), the counter signal A4 may correspond to bit number “1” and the inverse counter signal Ab4 may correspond to bit number “0”. Thus, the memory buffer 330 may perform the data write operation by using the second word buffer, and perform the data program operation by using the first word buffer.

Therefore, the write control command and the program control command may be changed by counting every 16-bytes, so as to alternately assign the first word buffer and the second word buffer of the memory buffer 330 for performing the data write operation and the data program operation.

In summary, according to the memory device and the operation method thereof of the disclosure, the memory device may synchronously perform the data write operation and the data program operation, so as to reduce the time for data programming. Moreover, the memory device may further use the optimized program bias voltage for pre-cycling operation to also reduce the time for system code programming. In addition, the memory buffer may further effectively save the use of memory space of the memory buffer in the data write operation and the data program operation.

The present invention is suitable for making miniaturized memory devices, so as to increase the total number of dies on a wafer. Therefore, the production cost and energy consumption of manufacturing a single IC are reduced, and the production energy consumption of subsequent packaging is also reduced, thereby reducing carbon emissions in the process of producing flash memory. In addition, since the number or size of memory buffers can be reduced, the die size and pump size (i.e. the write current) of the memory device can also be reduced.

Besides, the memory devices of the present disclosure may be a code storage flash memory, for example, a code storage NOR flash memory. In addition, the memory devices of the present disclosure may be used in computer, communication, consumer, mobile, automotive, industrial applications, wearable, IoT and other demanding designs that call for low power in tiny packages. For example, the memory devices of the present disclosure can used for achieving instant-on and real time 2D/3D image rendering, or ADAS (Advanced Driver Assist Systems).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An operation method of a memory device, comprising:
receiving a writer mode command to operate the memory device to perform a data write operation by a system control logic;
during a data write period of the data write operation, receiving and writing a plurality of word data into a memory buffer by the system control logic, and performing a data program operation by the memory buffer; and
during a data program period of the data program operation, programming the plurality of word data into the memory cell by the memory buffer,
wherein the data program period is partial overlapped with the data write period.

2. The operation method according to claim 1, wherein there is a data write clock latency between a start time of the write data period and a start time of the data program period.

3. The operation method according to claim 2, wherein the data write clock latency is related to an error correction code word length.

4. The operation method according to claim 1, wherein the plurality of word data comprise N word data, and when the system control logic receives and writes a second word data into the memory buffer in a current word cycle, the memory buffer also programs a first word data which received from a previous word cycle into the memory cell.

5. The operation method according to claim 4, wherein when the system control logic finishes receiving and writing an N-th word data into the memory buffer, the memory buffer starts to program an (N-1)-th word data into the memory cell.

6. The operation method according to claim 5, wherein the memory buffer programs the N-th word data into the memory cell after the data write operation is completed.

7. The operation method according to claim 1, further comprising:
receiving a chip select signal by a system control logic,
wherein when a voltage level of the chip select signal is changed from a first voltage level to a second voltage level, the system control logic starts to receive the writer mode command,
wherein when a voltage level of the chip select signal is changed from the second voltage level to the first voltage level, the system control logic finishes to receive and write the plurality of word data into the memory buffer.

8. The operation method according to claim 1, further comprising:
receiving a starting programming address by the system control logic, so that the memory buffer programs the plurality of word data into the memory cell according to the starting programming address.

9. The operation method according to claim 1, wherein the step of receiving and writing the plurality of word data into the memory buffer by the system control logic comprises:
generating a write word address to the memory buffer by an address counter, so that the memory device writes the plurality of word data into the memory buffer according to the write word address.

10. The operation method according to claim 1, the step of programming the plurality of word data into the memory cell by the memory buffer comprises:
generating a program word address to the memory buffer by an address counter, so that the memory device programs the plurality of word data into the memory cell from the memory buffer according to the program word address.

11. The operation method according to claim 10, the step of programming the plurality of word data into the memory cell by the memory buffer further comprises:
providing the program word address to a word line decoder and a bit line decoder of the memory cell by the address counter; and
programing the plurality of word data into the memory cell of a memory array.

12. The operation method according to claim 1, further comprising:
generating a write control command and a program control command to the memory buffer by an address counter;
assigning one of a first word buffer and a second word buffer of the memory buffer for performing the data write operation according to the write control command by the memory device; and
assigning another one of the first word buffer and the second word buffer of the memory buffer for performing the data program operation according to the program control command by the memory device.

13. The operation method according to claim 12, wherein the address counter comprises a plurality of flip-flops, and a data output terminal and an inverse data output terminal of one of the plurality of flip-flops is configured to output the write control command and the program control command.

14. The operation method according to claim 1, wherein when the plurality of word data is read out from the memory cell, the system control logic executes an error correcting code operation.

15. The operation method according to claim 1, wherein the memory device performs a normal program operation by using a first program bias voltage, and the memory device performs the data program operation by using a second program bias voltage, wherein the first program bias voltage is different from the second program bias voltage.

16. The operation method according to claim 15, wherein the second program bias voltage is higher than the first program bias voltage.

17. The operation method according to claim 1, wherein the plurality of word data comprises a system code.

18. The operation method according to claim 17, wherein the system code is a boot-up code.

19. The operation method according to claim 1, wherein the system control logic receive the plurality of word data through a serial peripheral interface or a quick path interconnect interface.

20. A memory device, comprising:
a memory cell;
a memory buffer, coupled to the memory cell; and
a system control logic, coupled to the memory buffer, and configured to receive a writer mode command to operate the memory device to perform a data write operation,
wherein during a data write period of the data write operation, the system control logic receives and writes a plurality of word data into the memory buffer, and the memory buffer performs a data program operation,
wherein during a data program period of the data program operation, the memory buffer programs the plurality of word data into the memory cell, and the data program period is partial overlapped with the data write period.
